(19) United States
(12) Patent Application Publication
(10) Pub. No.: US 2007/0257348 A1
(43) Pub. Date: Nov. 8, 2007

(54) Multiple chip package module and method of fabricating the same

(75) Inventor: Jun-Young Yang, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/429,160

(22) Filed: May 8, 2006

(51) Int. Cl. H01L 23/02

(52) U.S. Cl. 257/686

(57) ABSTRACT

A multiple chip package module comprises a first substrate, a first chip, an inverted first semiconductor unit, a first encapsulant, and a second semiconductor unit. The first chip is disposed on the first substrate. The inverted first semiconductor unit is stacked over the first chip. The first encapsulant covers the first chip and the first semiconductor unit, and the first encapsulant has an opening to expose a part of the first semiconductor unit. The second semiconductor unit comprises a plurality of first bumps on a bottom side of the second semiconductor unit, the second semiconductor unit mounted on the first semiconductor unit in the opening, and is electrically connected to the first semiconductor unit through the first bumps.

### BACKGROUND OF THE INVENTION

1. Field of the Invention

The invention relates in general to a package module and a method of fabricating the same, and more particularly to a multiple chip package module and a method of fabricating the same.

2. Description of the Related Art

Ongoing goals of the computer industry include higher performance, lower cost, increase miniaturization of components, and great packaging density of integrated circuits (“IC's”). As new generations of IC products are released, their functionality increases while the number of components decreases.

Semiconductor devices are constructed from a silicon or gallium arsenide wafer through a process that comprises a number of deposition, masking, diffusion, etching, and implanting steps. Usually, many individual devices are constructed on the same wafer. When the devices are separated into individual rectangular units, each takes the form of an IC die. In order to interface a die with other circuitry, it is common to mount it on a leadframe or on a substrate that is surrounded by a number of lead fingers. Each die has bonding pads that are then individually connected in a wire-bonding operation to the leadframe's lead finger pads using extremely fine gold or aluminum wires, or by flipped chip attachment.

Flip chip attachment consists of attaching a flip chip to a PCB or to another substrate. A flip chip is a semiconductor chip that has a pattern or array of terminals spaced around on an attachment surface on the chip for face-down mounting to a substrate. Generally, the attachment surface of the flip chip has one of the following electrical connectors: ball grid array (“BGA”) or slightly larger than IC carrier (“SLICC”). BGA is an electrical connector configuration having an array of minute solder balls disposed on the attachment surface of the flip chip for attaching to the substrate. SLICC is similar to the BGA, but has a smaller solder ball pitch and diameter than the BGA.

With the BGA or SLICC, the solder or other conductive ball arrangement on the flip chip must be a mirror image of the connecting bond pads on the PCB so that precise connection can be made. The flip chip is bonded to the PCB by melting (refluxing) the solder balls. The solder balls may also be replaced with a conductive polymer or gold stud bumps bonded using a conductive polymer.

Wire bonding attachment and TAB attachment generally begin with attaching a semiconductor chip to the surface of a small PCB with an appropriate adhesive such as an epoxy. With wire bonding attachment, wires are then attached, one at a time, to each bond pad on the semiconductor chip and extend to a corresponding metal lead or trace end on the PCB. With TAB, the ends of metal leads that are carried on an insulating tape are respectively attached to the bond pads on the semiconductor chip and to the lead or trace ends on the PCB. An encapsulant is then generally used to cover the bond wires and metal tape leads to prevent damage or contamination.

However, portable electronic products such as mobile telephones, mobile computers, and various consumer products require higher semiconductor functionality and performance in a limited footprint and minimal thickness and weight at the lowest cost. This has driven the industry to increase integration on the individual semiconductor chips.

### SUMMARY OF THE INVENTION

In view of the foregoing, it is an object of the present invention to provide a multiple chip package module and a method of fabricating the same. More chips therefore can be disposed in the multiple chip package module, which contributes to a more completed and optimized system inside package.

The invention achieves the above-identified object by providing a multiple chip package module, comprising a first substrate, a first chip, an inverted first semiconductor unit, a first encapsulant, and a second semiconductor unit. The first chip is disposed on the first substrate. The inverted first semiconductor unit is stacked over the first chip. The first encapsulant covers the first chip and the first semiconductor unit, and the first encapsulant has an opening to expose a part of the first semiconductor unit. The second semiconductor unit comprises a plurality of first bumps on a bottom side of the second semiconductor unit, the second semiconductor unit mounted on the first semiconductor unit in the opening, and is electrically connected to the first semiconductor unit through the first bumps.

It is another object of the invention to provide a method for fabricating a multiple chip package module, comprising steps of: (a) providing a first substrate; (b) mounting a first chip on the first substrate; (c) mounting a first semiconductor unit upside down over the first chip; (d) electrically connecting the first chip and first semiconductor unit to the first substrate respectively; (e) encapsulating the first chip and the first semiconductor unit and forming an opening over the first semiconductor unit to expose a part of the first semiconductor unit; (f) mounting a second semiconductor unit on the first semiconductor unit in the opening by soldering a plurality of first bumps of the second semiconductor unit onto the first semiconductor unit.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a cross sectional view illustrating a multiple chip package module according to the first embodiment of the present invention.

FIGS. 2A˜2E are cross sectional view illustrating the method of fabricating the multiple chip package module of FIG. 1.

FIG. 3 is a cross sectional view illustrating a multiple chip package module according to the second embodiment of the present invention.

FIGS. 4A˜4E, these are cross sectional view illustrating the method of fabricating the multiple chip package module of FIG. 3.

FIG. 5 is a cross sectional view illustrating a multiple chip package module according to the third embodiment of the present invention.

FIGS. 6A˜6D are cross sectional view illustrating the method of fabricating the multiple chip package module of FIG. 5.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

The multiple chip package module of the present invention includes an inverted semiconductor unit disposed at the top surface and exposing a part of the substrate thereof, so that another semiconductor unit can be mounted on the exposed part. It allows multiple chips to be gathered in single one package module.

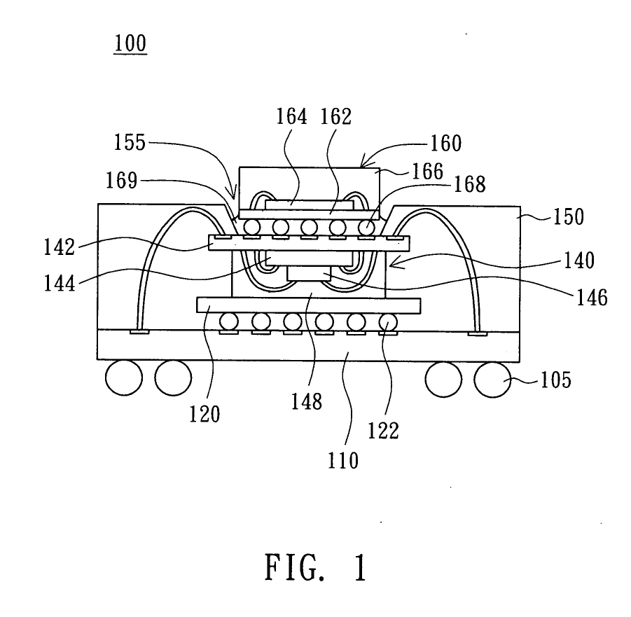

Referring to FIG. 1, it is a cross sectional view illustrating a multiple chip package module according to the first embodiment of the present invention. The multiple chip package module 100 of the present embodiment includes a substrate 110, a chip 120, a first semiconductor unit 140, an encapsulant 150, and a second semiconductor unit 160. The chip 120 is disposed on the substrate 110; preferably the chip 120 is electrically connected to the substrate 110 by several bumps 122 welded with the substrate 110. The inverted first semiconductor unit 140 is stacked over the chip 110. The encapsulant 150 covers the chip 110 and the first semiconductor unit 140, and the encapsulant 150 has an opening 155 to expose a part of the first semiconductor unit 140. The second semiconductor unit 160, having plural bumps 168 on a bottom side of the second semiconductor unit 160, is mounted on the first semiconductor unit 140 in the opening 155, and is electrically connected to the first semiconductor unit 140 through the bumps 168.

Semiconductor unit can be a sub-package with at least one chip mounted thereon. The first semiconductor unit 140, for example, is a sub-package, including a substrate 142, a chip 144, and an encapsulant 146. The substrate 142 is stacked over the chip 120. The chip 144 is mounted on and electrically connected to the substrate 142, such as by wire-bonding. The encapsulant 148 covers the chip 144 and the substrate 142. The first semiconductor unit 140 is mounted upside down over the chip 120, and the opening 155 of the encapsulant 150 exposes a part of the substrate 142. The first semiconductor unit 140 preferably carriers another chip 146, as shown in FIG. 1, or more chips for expand the capacity of the package 100. In addition, the second semiconductor 160 is preferably a sub-package, at least including a substrate 162, a chip 164, and encapsulant 166. The substrate 162 has several bumps 168 on the bottom surface. The chip 164 is mounted on and electrically connected to the top surface of the substrate 162, such as by wire-bonding. The encapsulant 166 covers the chip 164 and the substrate 162. Although FIG. 1 shows the details of the first and the second semiconductor unit 140 and 160, it is noted that the first and second semiconductor units in the multiple chip package module 100 are not limited thereto; the first semiconductor unit 140, for example, may include only one chip, and the second semiconductor unit 160 may include two chips.

Furthermore, another chip can be disposed on the chip 120 and wire-bonded to the substrate 110. More chips therefore can be disposed in the multiple chip package module 100, which contributes to a more completed and optimized system inside package.

The space between the first and the second semiconductor units 140 and 160 is preferably filled with an underfil 169. Several solder balls 105 are mounted on the bottom surface of the substrate 110 for electrically connecting to another substrate or printed circuit board.

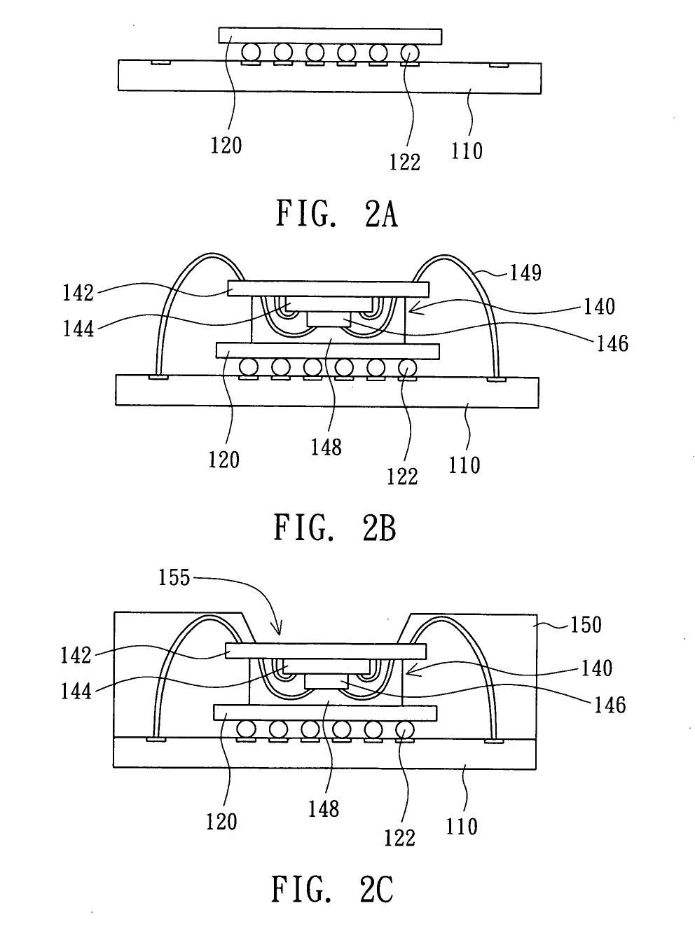

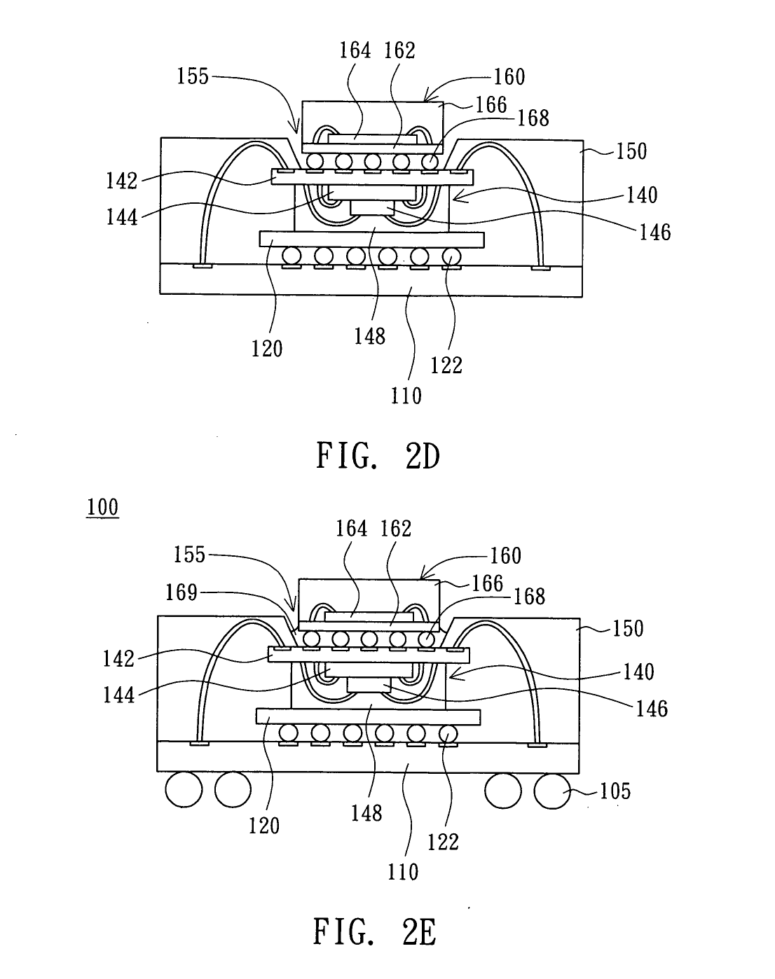

Referring to FIGS. 2A˜2E, these are cross sectional view illustrating the method of fabricating the multiple chip package module of FIG. 1. The method for fabricating the multiple chip package module includes following steps. Firstly, the substrate 110 is provided, and a chip 120 is mounted on the substrate 120 by welding bumps 122, as shown in FIG. 2A. Then, the first semiconductor unit 140 is mounted upside down over the chip 120, and electrically connected to the substrate 110 by wire-bonding, as shown in FIG. 2B. The chip 120 and the first semiconductor unit 140 are electrically connected to the substrate 110 through bumps 122 and wires 149 respectively. Next, the chip 120 and the first semiconductor unit 140 are covered by the encapsulant 150, and an opening 155 is formed over the first semiconductor unit 140 to expose a part of the substrate 142, as shown in FIG. 2C. Then, a second semiconductor unit 160 is mounted on the first semiconductor unit 140 in the opening 155 by soldering several bumps 168 of the second semiconductor unit 160 onto the first semiconductor unit 140, as shown in FIG. 2D. Finally, the space between the first and the second semiconductor units 140 and 160 are filled with an underfill 169, and several solder balls 105 are formed on the bottom surface of the substrate 110, as shown in FIG. 2E. The second semiconductor unit of various function can be assembled in the package module 100 to extent and diverse the function. Further, the multiple chip package module having specific function can be made more quickly because the second semiconductor unit can be assembled on the top of pre-package equipped with basic function when clients give an order.

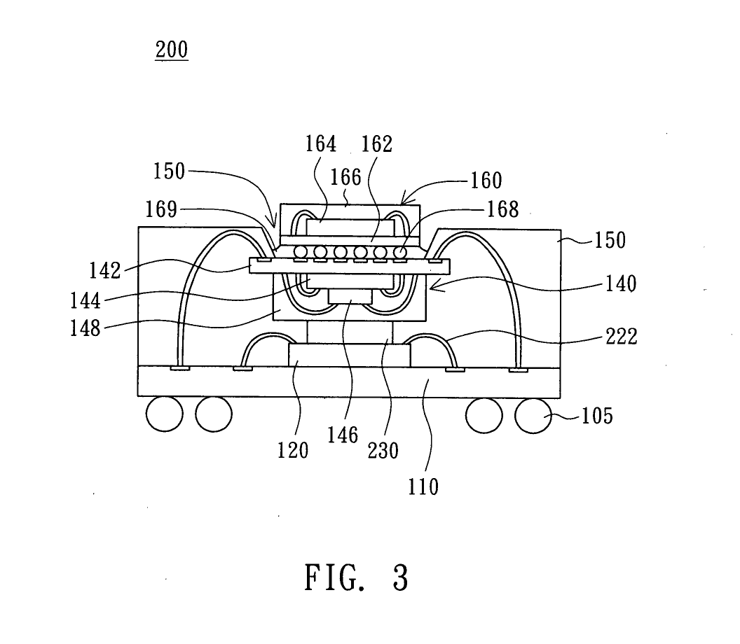

FIG. 3 is a cross sectional vies illustrating a multiple chip package module according to the second embodiment of the present invention. The differences between the first and the second embodiment are merely connection between chip 120 and substrate 110, and connection between chip 120 and first semiconductor unit 140. These differences will be mentioned in detail in the following paragraph, and the description of the similar elements with the same numerical labels will be omitted.

Referring to FIG. 3, the multiple chip package module 200 of the present embodiment includes a substrate 110, a chip 120, a first semiconductor unit 140, an encapsulant 150, and a second semiconductor unit 160. The chip 120 is disposed on the substrate 110; preferably the chip 120 is electrically connected to the substrate 110 by wires 222. The inverted first semiconductor unit 140 is stacked over the chip 110. The multiple chip package module further includes a interposer 230 interposed between the chip 120 and the first semiconductor unit 140. The interposer 23 is preferably a silicon spacer or a polyimide film. The interposer 230, which separates the chip 120 from the first semiconductor unit 140, provides a gap for wires 222 which stretch from the chip 120 to the substrate 110. The encapsulant 150 covers the chip 110, the interposer 230 and the first semiconductor unit 140, and has an opening 155 to expose a part of the first semiconductor unit 140. The second semiconductor unit 160 is mounted on the first semiconductor unit 140 in the opening 155.

Semiconductor unit can be a sub-package with at least one chip mounted thereon. Although FIG. 3 shows that two chips 144 and 146 disposed in the first semiconductor unit 140 and one chip 164 disposed in the second semiconductor unit 160, it is noted that the first and second semiconductor units in the package 200 are not limited thereto; the second semiconductor unit 160, for example, may include two chips, or the first semiconductor unit 140 may include only one.

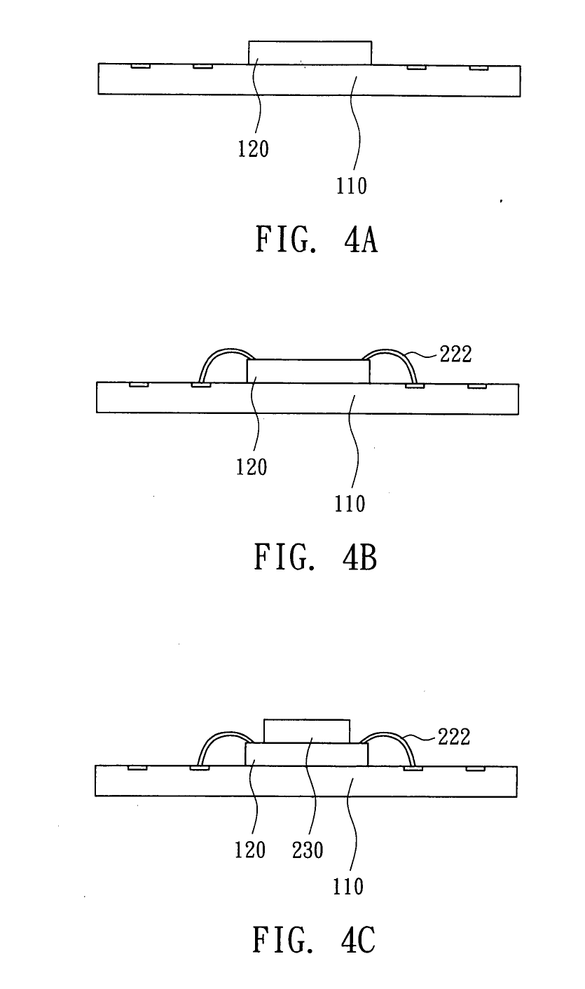

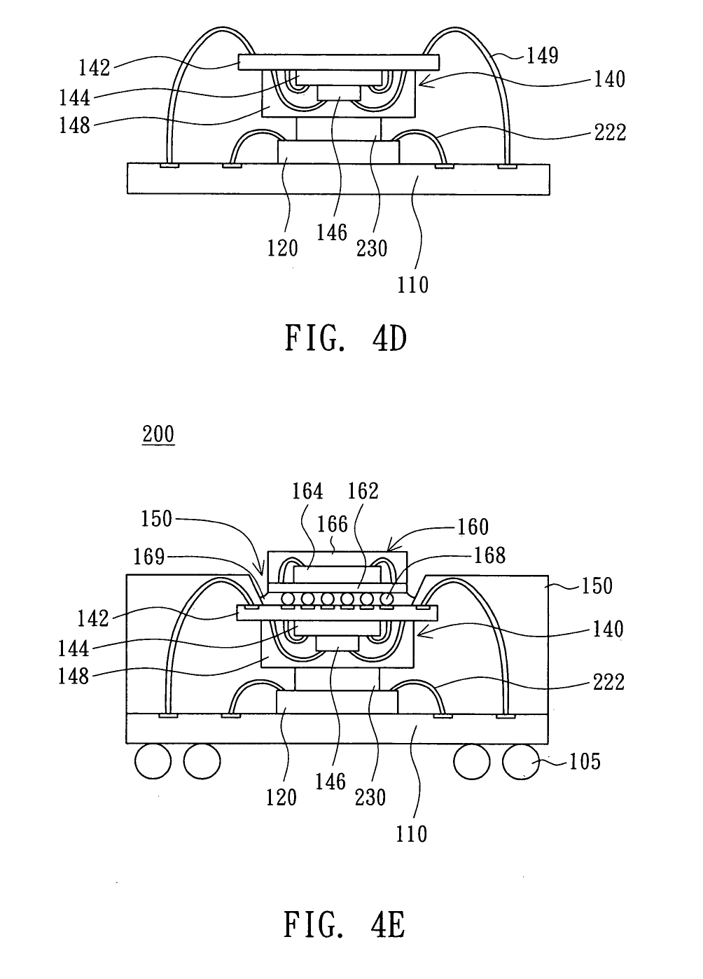

Referring to FIGS. 4A˜4E, these are cross sectional view illustrating the method of fabricating the multiple chip package module of FIG. 3. The method for fabricating the multiple chip package module 200 includes following steps. Firstly, the substrate 110 is provided, and a chip 120 is mounted on the substrate 120 as shown in FIG. 4A. Then, the chip is electrically connected to the substrate 110 by wires 222, as shown in FIG. 4B. Next, an interposer 230 is disposed on the chip 120, as shown in FIG. 4C. Then, the first semiconductor unit 140 is mounted upside down over the chip 120, and electrically connected to the substrate 110 by wire-bonding, as shown in FIG. 4D. The chip 120 and the first semiconductor unit 140 are electrically connected to the substrate 110 by wires 222 and 149 respectively. Then, the encapsulant 150 and the second semiconductor unit 160 are sequentially disposed to complete the multiple chip package module 200 of FIG. 4E, in the similar way as mentioned in first embodiment.

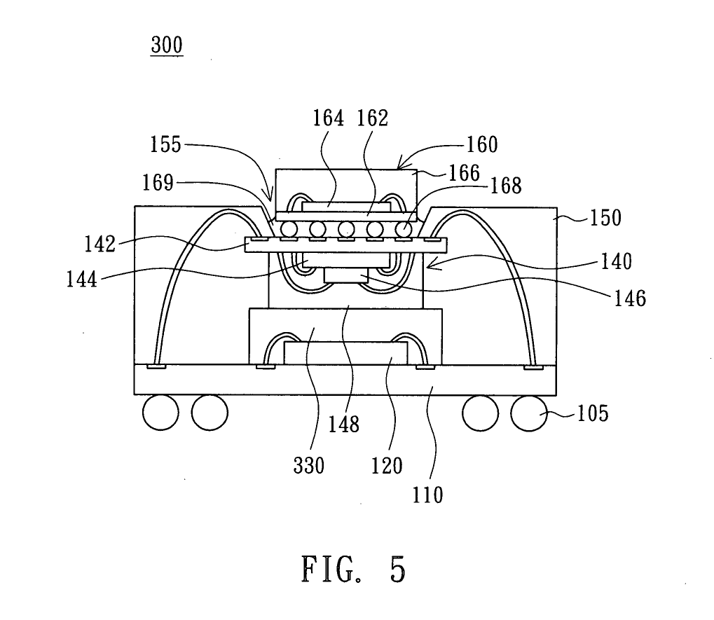

FIG. 5 is a cross sectional view illustrating a multiple chip package module according to the third embodiment of the present invention. The differences between the second and the third embodiment are merely connection between chip 120 and substrate 110, and connection between chip 120 and first semiconductor unit 140. These differences will be mentioned in detail in the following paragraph, and the description of the similar elements with the same numerical labels will be omitted.

Referring to FIG. 5, the multiple chip package module 300 of the present embodiment includes a substrate 110, a chip 120, a first semiconductor unit 140, a first encapsulant 330, a second encapsulant 150, and a second semiconductor unit 160. The chip 120 is disposed on the substrate 110; preferably the chip 120 is electrically connected to the substrate 110 by wires 222. The first encapsulant 330 covers the chip 120 and wires 222. The inverted first semiconductor unit 140 is stacked over the. chip 110, and preferably stacked on the first encpasulant 330. The encapsulant 150 covers the chip 110, the interposer 230 and the first semiconductor unit 140, and has an opening 155 to expose a part of the first semiconductor unit 140. The second semiconductor unit 160 is mounted on the first semiconductor unit 140 in the opening 155.

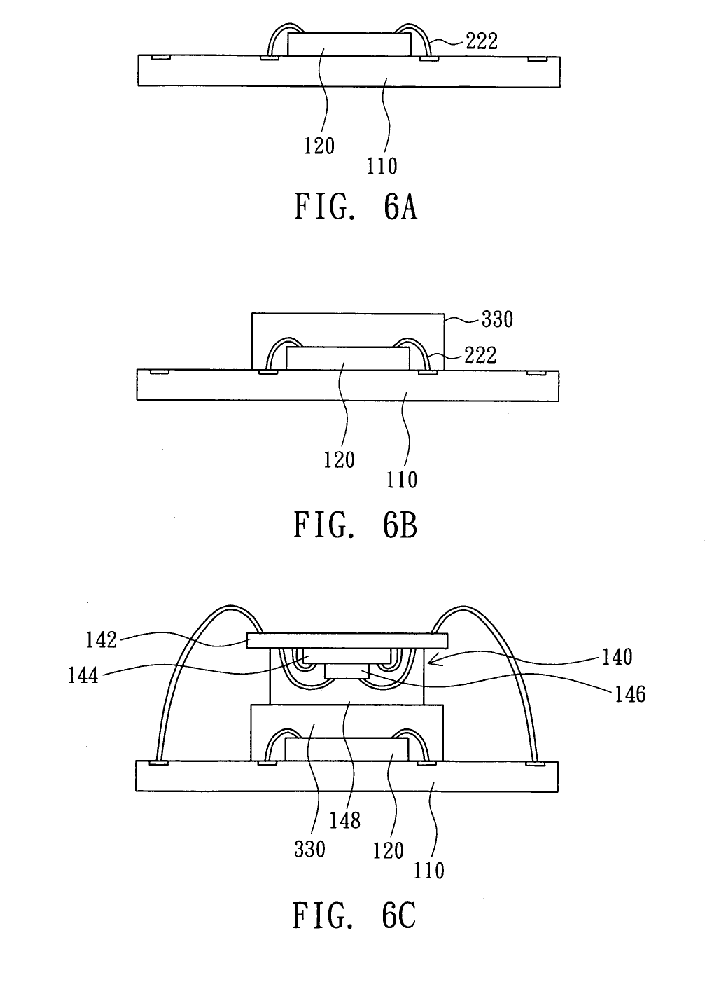

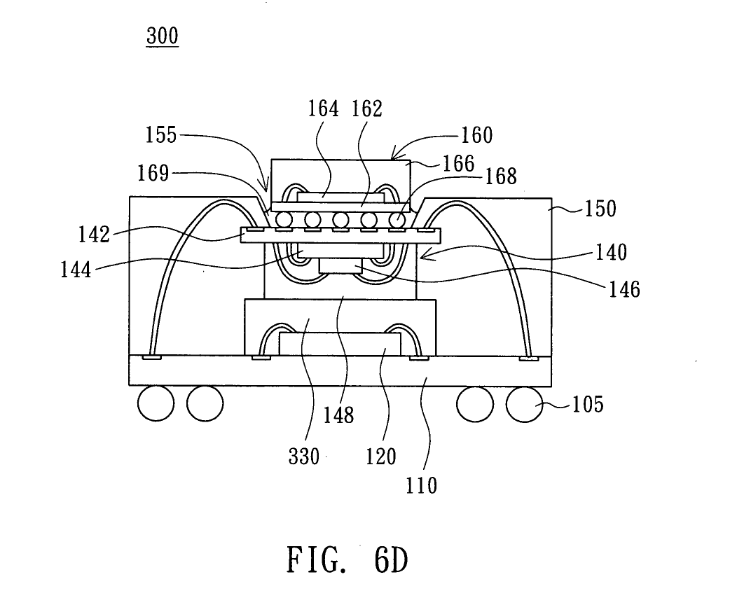

Referring to FIGS. 6A˜6D, these are cross sectional view illustrating the method of fabricating the multiple chip package module of FIG. 5. The method for fabricating the multiple chip package module 300 includes following steps. Firstly, the substrate 110 is provided, and a chip 120 is wire-bonded to the substrate 120 by wires 222, as shown in FIG. 6A. Then, the first encapsulant 330 covers the chip 120 and wires 222, as shown in FIG. 6B. Next, the first semiconductor unit 140 is mounted upside down over the chip 120, preferably mounted on the first encapsulant 330, and electrically connected to the substrate 110 by wire-bonding, as shown in FIG. 6C. The chip 120 and the first semiconductor unit 140 are electrically connected to the substrate 110 wires 222 and 149 respectively. Then, the encapsulant 150 and the second semiconductor unit 160 are sequentially disposed to complete the multiple chip package module 200 of FIG. 6D, in the similar way as mentioned in first embodiment.

As described hereinbefore, the multiple chip package module and the method for fabricating the same has many advantages. More chips therefore can be disposed in the multiple chip package module, which contributes to a more shrinked-size and optimized system inside package. The second semiconductor unit of various function can be assembled in the package module to extent and diverse the function. Further, the multiple chip package module having specific function can be fabricated more quickly and efficiently because the second semiconductor unit can be assembled on the top of pre-package equipped with basic function when clients give an order. It allows to speed up and simplify the manufacture process due to highly flexible design and diversity resulted from combination rather than giant and complicated circuit.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A multiple chip package module, comprising:
a first substrate;
a first chip disposed on the first substrate;
an inverted first semiconductor unit, stacked over the first chip;
a first encapsulant covering the first chip and the first semiconductor unit, the first encapsulant having an opening to expose a part of the first semiconductor unit; and
a second semiconductor unit, comprising a plurality of first bumps on a bottom side of the second semiconductor unit, the second semiconductor unit mounted on the first semiconductor unit in the opening, and electrically connected to the first semiconductor unit through the first bumps.

2. The multiple chip package module according to claim 1 further comprising a plurality of second bumps electrically connecting the first chip and the first substrate.

3. The multiple chip package module according to claim 1 further comprising a plurality of wires electrically connecting the first chip and the first substrate.

4. The multiple chip package module according to claim 3 further comprising a second encapsulant covering the first chip.

5. The multiple chip package module according to claim 3 further comprising:
an interposer, interposed between the first chip and the first semiconductor unit.

6. The multiple chip package module according to claim 1, wherein the first semiconductor unit is a sub-package, at least comprising:
a second substrate, stacked over the first chip;
a second chip, mounted on the second substrate; and
a second encapsulant, covering the second chip and the second substrate;
wherein the first semiconductor unit is mounted upside down over the first chip, and the opening of the first encapsulant exposes a part of the second substrate.

7. The multiple chip package module according to claim 1, wherein the second semiconductor unit is a sub-package, at least comprising:
a second substrate, comprising the first bumps on a bottom surface thereof;
a second chip, mounted on a top surface of the second substrate; and
a second encapsulant, covering the second chip and the second substrate.

8. The multiple chip package module according to claim 1 further comprising:
an underfill, filling between the first and the second semiconductor units.

9. The multiple chip package according to claim 1 further comprising:
a plurality of solder balls, mounted on a bottom surface of the first substrate.

10. A method for making a multiple chip package module, comprising:
providing a first substrate;
mounting a first chip on the first substrate;
mounting a first semiconductor unit upside down over the first chip;
electrically connecting the first chip and first semiconductor unit to the first substrate respectively;
encapsulating the first chip and the first semiconductor unit and forming an opening over the first semiconductor unit to expose a part of the first semiconductor unit;
mounting a second semiconductor unit on the first semiconductor unit in the opening by soldering a plurality of first bumps of the second semiconductor unit onto the first semiconductor unit.

11. The method according to claim 10, further comprising a plurality of second bumps electrically connecting the first chip and the first substrate.

12. The method according to claim 10 further comprising a plurality of wires electrically connected the first chip and the first substrate.

13. The method according to claim 12 further comprising:
encapsulating the first chip.

14. The method according to claim 12 further comprising:
providing an interposer interposed between the first chip and the first semiconductor unit.

15. The method according to claim 10, wherein the first semiconductor unit is a sub-package, at least comprising:
a second substrate, stacked over the first chip; a second chip, mounted on the second substrate; and
a second encapsulant, covering the second chip and the second substrate;
wherein the second semiconductor unit is mounted upside down over the first semiconductor unit, and the opening of the first encapsulant expose a part of the second substrate.

16. The method according to claim 10, wherein the first semiconductor unit is a sub-package, at least comprising:
a second substrate, comprising the first bumps on a bottom surface thereof;
a second chip, mounted on a top surface of the second substrate; and
a second encapsulant, covering the second chip and the second substrate.

17. The method according to claim 10 further comprising:
filling an underfill between the first and the second semiconductor units.

18. The method according to claim 10 further comprising: forming a plurality of solder balls on a bottom surface of the first substrate.
